(19) United States
(12) Patent Application Publication
(10) Pub. No.: US 2025/0169382 A1
(43) Pub. Date: May 22, 2025

(54) PHASE-CHANGE MEMORY CELL

(71) Applicants: COMMISSARIAT À L'ÉNERGIE ATOMIQUE ET AUX ÉNERGIES ALTERNATIVES, Paris (FR); STMicroelectronics International N.V., Geneva (CH)

(72) Inventors: Gabriele NAVARRO, Grenoble (FR); Clement DE CAMARET, Grenoble (FR)

(73) Assignees: COMMISSARIAT À L'ÉNERGIE ATOMIQUE ET AUX ÉNERGIES ALTERNATIVES, Paris (FR); STMicroelectronics International N.V., Geneva (CH)

(21) Appl. No.: 18/939,358

(22) Filed: Nov. 6, 2024

(30) Foreign Application Priority Data
Nov. 17, 2023 (FR) 2312658

(51) Int. Cl. H10N 70/20; H10N 70/00

(52) U.S. Cl. CPC H10N 70/231; H10N 70/021; H10N 70/063; H10N 70/066; H10N 70/821; H10N 70/8828; H10N 70/883

(57) ABSTRACT

The present disclosure relates to a phase-change memory cell of the confined type comprising: an insulating region; a first confined region made of a first alloy of germanium, antimony, and tellurium laterally surrounded by the insulating region, the first alloy forming entirely the first confined region; and a second region made of a second alloy of germanium, antimony, and tellurium, the second alloy comprising proportions different from the proportions of the first alloy, the second region overlapping the insulating region and the first region.

### CROSS-REFERENCE TO RELATED APPLICATION(S)

This application claims the priority benefit of French patent application number 23/12658, filed on Nov. 17, 2023, entitled “Cellule mémoire à changement de phase,” which is hereby incorporated by reference to the maximum extent allowable by law.

### TECHNICAL FIELD

The present description relates generally to electronic devices, more particularly to phase-change memories and the cells of such memories.

### DESCRIPTION OF THE RELATED ART

In a phase-change memory, the phase-change material of each cell is able to alternate, under the effect of a rise in temperature, between an amorphous, electrically resistive phase, and a crystalline, electrically conductive phase. The amorphous and crystalline phases of a cell's phase-change material enable two memory states to be defined for this cell, corresponding, for example, to logic values 0 and 1 respectively.

Phase-change memories are currently integrated in many types of electronic devices, such as microcontrollers. In some applications, phase-change memories are subjected to high temperatures, which can cause loss of data stored in memories. In the automotive field, for example, high-temperature memory stability specifications may involve the memory guaranteeing persistence of the information stored therein for more than ten years at a temperature of around 150° C., and for around two hours at a temperature of around 250° C. When a phase-change memory is exposed to such temperatures, the cells whose material is initially in the amorphous phase may undergo unintentional crystallization, resulting in an undesirable modification of their logic values, thus compromising the integrity of the data stored in the memory.

To overcome this drawback, memory cells based on an alloy of germanium, antimony, and tellurium (GeSbTe, also known by the acronym “GST”) with a high germanium content, e.g., over 35% in atomic percent, have been proposed. In these cells, the high germanium content allows the crystallization of the material at high temperatures, e.g., higher than 250° C., to be delayed. However, delaying crystallization of the material penalizes the transition from amorphous to crystalline phase in these cells. In cells based on GeSbTe with a high germanium content, the transition from the amorphous phase leads instead to the formation of a polycrystalline phase comprising grains made up of a stable stoichiometric phase, e.g., a Ge₂Sb₂Te₅, GeSb₂Te₄, Sb₂Te₃, etc., separated by germanium-rich grain boundaries. This causes a very significant drift in memory cell resistance over time, this drift being exacerbated by exposure to high temperatures. In such cells, the resistance of the supposedly crystalline phase tends towards that of the amorphous phase, making it very difficult to discriminate between the two memory states.

A further drawback of memory cells based on a GeSbTe alloy with a high germanium content is that, when these cells undergo a step of initializing aimed at forming an active region, for example in the shape of a mushroom, within each of these cells, a partial expulsion of the germanium present in excess in the active region, and of germanium-rich areas at the periphery of the active region are observed. This creates undesirable heterogeneities between the memory cells.

### BRIEF SUMMARY

There is a use for improving existing phase-change memory cells. In particular, it would be desirable to produce phase-change memory cells with improved temperature resistance, without these cells being affected by resistance drift when in the crystalline phase.

For this purpose, one embodiment provides a confined-type phase-change memory cell comprising:
an insulating region;
a first confined region made of a first alloy of germanium, antimony, and tellurium laterally surrounded by the insulating region, the first alloy entirely forming the first confined region; and
a second region made of a second alloy of germanium, antimony, and tellurium, the second alloy comprising proportions different from the proportions of the first alloy, the second region overlapping the insulating region and the first region.

According to one embodiment, the second region is common to several memory cells, the first region of each memory cell being distinct from those of the other memory cells, each memory cell further comprising a lower electrode distinct from those of the other memory cells.

According to one embodiment, the second region of each memory cell is distinct from those of the other memory cells, each memory cell further comprising an upper electrode distinct from those of the other memory cells.

According to one embodiment, the first alloy has:
an atomic concentration of germanium of between 35 and 65%; and
a ratio of atomic concentration of antimony to atomic concentration of tellurium of between 1 and 5.

According to one embodiment, the second alloy has:
an atomic concentration of germanium of between 40 and 80%; and
a ratio of atomic concentration of antimony to atomic concentration of tellurium of between 0.2 and 1.

According to one embodiment:
the first region has a thickness higher than 5 nm, preferably higher than 10 nm; and
the second region has a thickness higher than 5 nm, preferably higher than 10 nm.

According to one embodiment, the cell further comprises a third region made of the second alloy located on the side of a face of the insulating region opposite the second region, the insulating region and the first region being located on, and in contact with, the third region.

According to one embodiment, the second region is located on, and in contact with, the insulating region and the first region.

According to one embodiment, the cell further comprises a fourth region made of a third alloy of germanium, antimony, and tellurium, different from the first and second alloys, interposed between the first and second regions.

According to one embodiment, the cell further comprises fourth and fifth regions made of a third alloy of germanium, antimony, and tellurium different from the first and second alloys, and:
the fourth region is interposed between the first and second regions; and
the fifth region is interposed between the first and third regions.

According to one embodiment, the first region is U-shaped, the interior of the U formed by the first region being completely filled with a dielectric material.

According to one embodiment, the first region is L-shaped.

According to one embodiment, a spacer made of silicon nitride coats the upper face of the horizontal part, and a flank of the vertical part of the L formed by each first region.

According to one embodiment, the first region has a maximum lateral dimension being strictly smaller than that of the second region.

According to one embodiment, the first region has a thickness strictly less than that of the second region.

One embodiment provides a phase-change memory device comprising a plurality of memory cells as described.

One embodiment provides a method of manufacturing a phase-change memory cell comprising the following successive steps:
a) forming an insulating region;
b) forming an opening in the insulating region;
c) filling the opening with a first region made of a first alloy of germanium, antimony, and tellurium laterally surrounded by the insulating region; and
d) depositing, on the insulating region and the first region, a second region made of a second alloy of germanium, antimony, and tellurium, the second alloy comprising proportions different from the proportions of the first alloy, the second region overlapping the insulating region and the first region.

According to one embodiment, the cell comprises a single stack of phase-change materials consisting of the first and second regions.

According to one embodiment, the cell comprises a single stack of phase-change materials consisting of the first, second, and third regions.

According to one embodiment, the cell further comprises first and second electrodes located on either side of the first region, one of these electrodes being located on, and in contact with, the second region.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is a partial schematic cross-sectional view of a phase-change memory cell according to one embodiment;

FIG. 2 is a graph illustrating the chemical element contents of alloys used to produce the regions made of phase-change material of the cell shown in FIG. 1;

FIG. 3 is a partial schematic cross-sectional view of a structure obtained at the end of a step of initializing the memory cell shown in FIG. 1;

FIG. 4 is a partial schematic cross-sectional view of a phase-change memory cell according to one embodiment;

FIG. 5 is a partial schematic cross-sectional view of a phase-change memory cell according to one embodiment; and

FIG. 6 is a partial schematic cross-sectional view of a structure comprising two phase-change memory cells according to one embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the elements and circuits for controlling the phase-change memory cells of the memory devices described, which may in particular include selection and electrical connection elements, are not detailed, as the embodiments described are compatible with all or most of the usual phase-change memory cell control elements and circuits, optionally subject to any adaptations available to those skilled in the art based on the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

In the following description, the terms “insulating” and “conductive” mean electrically insulating and electrically conductive respectively, unless otherwise specified.

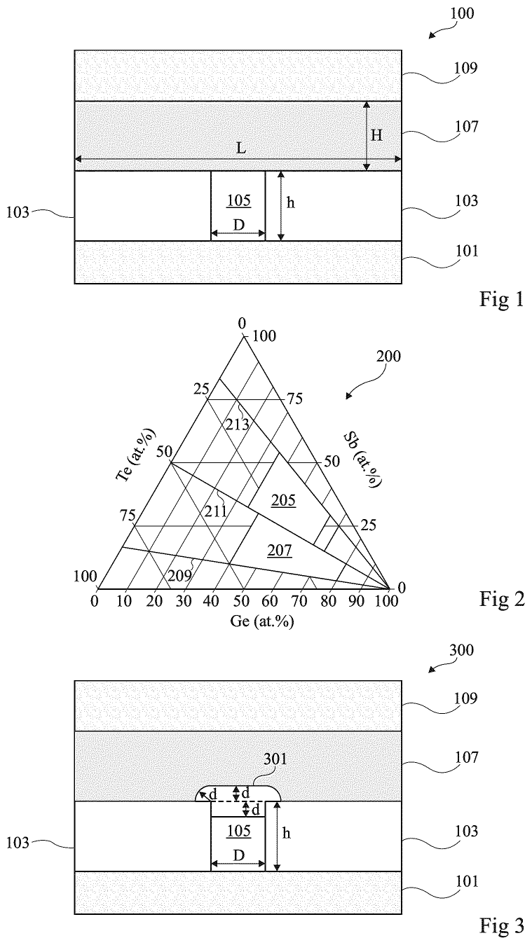

FIG. 1 is a partial schematic cross-sectional view of a phase-change memory cell 100 according to one embodiment. For example, memory cell 100 is part of a memory device comprising several memory cells identical or similar to memory cell 100, for example arranged in a matrix in rows and columns. By way of example, the memory device of which memory cell 100 is part comprises several thousand or several million memory cells. More particularly, FIG. 1 illustrates a confined-type memory cell.

In the example shown, memory cell 100 comprises a conductive layer 101. The conductive layer 101 constitutes, for example, a first electrode (the lower electrode, in the orientation shown in FIG. 1) of the memory cell 100. The conductive layer 101 is, for example, located on and in contact, through its lower face, with a selector not shown in FIG. 1. In this case, the selector is, for example, a transistor, such as a CMOS (Complementary Metal-Oxide-Semiconductor) transistor or a bipolar (Bipolar Junction Transistor, BJT) transistor, or a diode. When viewed from above, the conductive layer 101 has any shape, such as rectangular, elliptical, square, or circular shape. By way of example, the conductive layer 101 is made of a metal or metal alloy.

In the example illustrated, the memory cell 100 further comprises an insulating region 103 coating the conductive layer 100. In this example, the insulating region 103 is located on, and in contact with, the upper face of the conductive layer 101. By way of example, the insulating region 103 is made of a nitride, e.g., silicon nitride (SiN) or germanium nitride (GeN), or an oxide, e.g., silicon dioxide (SiO₂).

In the example shown, the memory cell 100 further comprises a confined region 105 made of a phase-change material. In this example, the region 105 is located in the insulating region 103. In the example illustrated, the region 105 extends vertically through the entire thickness of the insulating region 103, i.e., from a face of the insulating region 103 opposite the conductive layer 101 (the upper face of the insulating region 103, in the orientation shown in FIG. 1) to the upper face of the conductive layer 101. In the example shown, region 105 is flush with the upper face of insulating region 103. Furthermore, in this example, the insulating region 103 laterally borders the region 105, the insulating region 103 being located on, and in contact with, the side walls, or flanks, of the region 105. In the example shown in FIG. 1, region 105 is located on, and in contact with, a portion of the upper face of conductive layer 101 not coated by insulating region 103. In the example shown, region 105 made of phase-change material fills, i.e., completely fills, an opening or cavity formed in insulating region 103. In other words, the phase-change material completely forms the confined region 105.

In the example illustrated, the region 105 made of phase-change material has a maximum lateral dimension D. When viewed from above, the region 105 has any shape, for example identical to that of the conductive layer 101. For example, when viewed from above, the region 105 has a rectangular, elliptical, square, or circular shape. In these cases, the maximum lateral dimension D of region 105 corresponds respectively to the length, major axis, side or diameter of region 105. By way of example, the dimension D is between 1 and 100 nm, for example between 10 and 50 nm. Furthermore, in the example shown in FIG. 1, the region 105 has a height, or thickness, substantially equal to a height h, or thickness, of the insulating region 103. By way of example, the height h is higher than 5 nm, preferably higher than 10 nm. For example, the height h is less than, or equal to, 100 nm.

In the example shown, the memory cell 100 further comprises a further region 107 made of a phase-change material different from that of region 105. In the example shown, region 107 coats, or overlaps, insulating region 103. In this example, region 107 is located on, and in contact with, the upper face of insulating region 103. In addition, region 107 coats, or overlaps, region 105 made of phase-change material. In the example shown, region 107 is located on, and in contact with, the upper face of region 105.

In the example illustrated, the region 107 made of phase-change material has a height, or thickness, H and a maximum lateral dimension L. The height H of the region 107 is, for example, higher than the height h of the region 105. For example, the height H is higher than 5 nm, preferably higher than 10 nm. The height H is, for example, less than, or equal to, 200 nm. Furthermore, the maximum lateral dimension L of region 107 is strictly higher, for example about ten times higher, than the maximum lateral dimension D of the underlying region 105. When viewed from above, the region 107 has any shape, for example identical to that of the conductive layer 101 and/or that of the region 105. For example, when viewed from above, the region 107 has a rectangular, elliptical, square, or circular shape. In these cases, the maximum lateral dimension L of the region 107 corresponds respectively to the length, major axis, side, or diameter of the region 107. By way of example, the dimension L is between 5 and 500 nm, for example between 20 and 300 nm.

In the example shown, the memory cell 100 further comprises a further conductive layer 109. As an example, the conductive layer 109 forms a second electrode (the upper electrode, in the orientation shown in FIG. 1), of the memory cell 100. The conductive layer 109, for example, coats the region 107 made of phase-change material, the conductive layer 109 being located, for example, on, and in contact with by its lower face, the upper face of the region 107. When viewed from above, the conductive layer 109 has any shape, for example identical to that of the conductive layer 101, and/or that of the region 105, and/or that of the region 107. When viewed from above, the conductive layer 109 has, for example, a rectangular, elliptical, square, or circular shape.

As an example, conductive layer 109 is made of a metal, e.g., tungsten, or made of a metal alloy. By way of example, conductive layer 109 is made of a metal nitride, e.g., titanium nitride (TiN) or tantalum nitride (TaN). Alternatively, although not detailed in FIG. 1, at least one further intermediate metal layer, forming for example an intermediate electrode, may be interposed between the region 107 made of phase-change material and the conductive layer 109. In this case, each intermediate metal layer is titanium- or carbon-based, for example.

In memory cell 100, conductive layer 101 is, for example, insulated from conductive layers forming lower electrodes of other adjacent memory cells identical or similar to memory cell 100. This corresponds, for example, to a case where conductive layer 109 forms an upper electrode common to several or all memory cells of the memory device to which memory cell 100 belongs. In this case, memory cell 100 has, for example, lateral dimensions substantially equal to those of conductive layer 101.

By way of example, the conductive layer 101 is a conductor via connecting the region 105 made of phase-change material of the memory cell 100 to a selecting element, e.g., a transistor.

For example, region 107 is common to several memory cells 100 of the memory device. In this case, the region 105 of each memory cell 100 is for example distinct from the regions 105 of the other memory cells 100, the regions 105 being isolated from each other. The lower electrode of each memory cell 100 is then, for example, distinct from the lower electrodes of the other memory cells 100, the lower electrodes being isolated from each other.

As an alternative, the region 107 of each memory cell 100 may be distinct from the regions 107 of the other memory cells 100, the regions 107 being isolated from each other. Further, the conductive layer 109 of each memory cell 100 may be distinct from the conductive layers 109 of the other memory cells 100, the conductive layers 109 being isolated from each other. In this alternative, the region 107 and/or the conductive layer 109 of each memory cell 100 are, for example, surrounded by an insulating material.

The memory cell 100, for example, is produced performing a manufacturing method comprising the following successive steps:
a) depositing the conductive layer 101;
b) depositing, on the upper face side of the conductive layer 101, the insulating region 103;
c) forming, by photolithography and subsequent etching in the insulating region 103, a cavity, or opening, extending vertically through the thickness of the insulating region 103 from its upper face to the upper face of the conductive layer 101, the cavity having a maximum lateral dimension D, and a depth h;
d) forming the region 105 by depositing, on the upper face side of the insulating region 103, a first layer made of a first phase-change material filling the cavity formed in step c), and extending laterally over, and in contact with, the upper face of the insulating region 103, followed by planarizing, for example by chemical mechanical polishing (CMP), so as to remove portions of the first layer coating the upper face of the insulating region 103;
e) depositing, on the upper face side of the insulating region 103, a second layer made of a second phase-change material;
f) depositing, on the upper face side of the second layer made of the second phase-change material, the conductive layer 109; and
g) individualizing or delimiting the memory cell 100 by photolithography and subsequent etching of the stack formed by the insulating region 103, the second layer made of the second phase-change material, and the conductive layer 109, thus leading to the formation of the region 107 of maximum lateral dimension L.

Step g) of the above described method is for example followed by a further step h) of encapsulating the memory cell 100, comprising for example depositing an insulating layer, e.g., made of silicon nitride or silicon dioxide, coating the upper face and flanks of the conductive layer 109 as well as the flanks of the region 107 and the insulating region 103. Step h) can also be followed by a further step i) of forming contact recovery elements on the conductive layer 109 through the thickness of the encapsulating insulating layer.

FIG. 2 is a graph 200 showing the chemical element contents, or concentrations, of alloys used to produce regions 105 and 107 made of phase-change material in the memory cell 100 shown in FIG. 1. Specifically, FIG. 2 illustrates a case in which each region 105, 107 is made of an alloy of germanium, antimony, and tellurium (GeSbTe, also known by the acronym “GST”).

In the orientation shown in FIG. 2, the upward-pointing triangular-shaped graph 200 includes horizontal lines to represent variations in antimony (Sb) content, oblique lines to represent variations in germanium (Ge) content, and further oblique lines to represent variations in tellurium (Te) content. In graph 200, the germanium, antimony, and tellurium contents in the alloys of regions 105 and 107 are expressed in atomic percent (at. %) and range, for each chemical element, from 0 to 100%.

Graph 200 includes areas 205 and 207 corresponding respectively to the different chemical compositions possible for making the GeSbTe alloys of regions 105 and 107 from the phase-change material of memory cell 100. More specifically, areas 205 and 207 correspond to the ranges of atomic percentages of germanium, antimony, and tellurium used in the composition of the GeSbTe alloys of regions 105 and 107, respectively.

In the example shown, area 205 includes GeSbTe alloy compositions with an atomic concentration of germanium of between 35 and 65%, and an Sb/Te ratio, between the atomic concentration of antimony and the atomic concentration of tellurium, of between 1 and 5. Furthermore, in this example, area 207 includes alloy compositions with a germanium atomic concentration of between 40 and 80% and an Sb/Te ratio of between 0.2 and 1. In FIG. 2, graph 200 comprises a line 209 corresponding to an Sb/Te ratio equal to approximately 0.2, another line 211 corresponding to an Sb/Te ratio equal to approximately 1, and yet another line 213 corresponding to an Sb/Te ratio equal to approximately 5.

The germanium, antimony, and tellurium alloys of regions 105 and 107 can be doped, for example with nitrogen, carbon, oxygen, silicon atoms, etc.

One advantage of the memory cell 100 is that the phase-change material in the region 105 allows a segregated crystalline phase with a high crystal growth rate to be promoted, leading to the formation of large crystallites. In addition, the germanium content of this material allows good stability of the amorphous phase at high temperatures, e.g., higher than 150° C., to be guaranteed. In addition, the fact that region 105 is surrounded, or bordered, laterally by insulating region 103 allows higher current densities to be achieved than in region 107, and thus an amorphous phase to be formed in region 105 despite the fact that the material has an Sb/Te ratio of between 1 and 5.

Another advantage of the memory cell 100 is that the phase-change material of region 107 allows phenomena of germanium expulsion from region 105 as a result of the temperature rise applied to the memory cell 100 during a cell programming step to be limited or prevented. This ensures good thermal stability in region 105. In addition, the phase-change material of region 107 ensures good electrical conduction between the conductive layers 101 and 109 and region 105. The material of region 107 also allows migration, by diffusion, of tellurium of region 105 into region 107 to be limited or prevented.

FIG. 3 is a partial schematic cross-sectional view of a structure 300 obtained at the end of a step of initializing the memory cell 100 shown in FIG. 1. As an alternative, the structure 300 shown in FIG. 3 can be obtained during manufacture of the memory cell 100.

The structure 300 shown in FIG. 3 has elements in common with the memory cell 100 shown in FIG. 1. These common elements will not be detailed again below. The structure 300 shown in FIG. 3 differs from the memory cell 100 shown in FIG. 1 in that the structure 300 comprises a region 301 made of phase-change material interposed between regions 105 and 107.

In the example shown, a first part of the region 301 has, when viewed from above, a shape and lateral dimensions substantially identical to those of the region 105, and extends vertically through the thickness of the insulating region 103, from its upper face towards its lower face, to a depth d less than the thickness h of the insulating region 103. In this example, the region 105 has a height, or thickness, equal to the thickness h of the insulating region 103 minus the thickness d of the first part of the region 301. By way of example, the thickness d is less than, or equal to, 10% of the thickness h of the insulating region 103.

Furthermore, in the example illustrated, a second part of the region 301 has, when viewed from above, lateral dimensions strictly higher than those of the region 105 and extends vertically, within the thickness of the region 107, from its lower face towards its upper face, over a distance for example substantially equal to the thickness d of the first part of the region 301. In this example, the second part of the region 301 has, when viewed from above, a shape substantially identical to that of the region 105, and a maximum lateral dimension equal to the maximum lateral dimension of the region 105 plus twice the thickness d.

The phase-change material of region 301 is different from that of regions 105 and 107. For example, region 301 is made of a GeSbTe alloy having a chemical composition intermediate between that of the alloy of the underlying region 105 and that of the alloy of the overlapping region 107, in other words germanium, antimony, and tellurium contents between those of the phase-change material of region 105 and those of the phase-change material of region 107. For example, the alloy of region 301 has a germanium content and an Sb/Te ratio between those of alloys 205 and 207 of regions 105 and 107, respectively.

In the case where the structure 300 is obtained at the end of a step of initializing the memory cell 100 shown in FIG. 1, the region 301 is for example formed under the effect of a heating produced by a current flowing between the conductive layers 101 and 109 of the memory cell 100, leading to a mixing of the materials of the regions 105 and 107 in the vicinity of an interface between these regions. In a case where the structure 300 is obtained during the manufacture of the memory cell 100, the region 301 is for example formed, for example during a step implemented between steps d) and e) of the method previously described in relation to FIG. 1, by an operation of depositing a third layer made of a third phase-change material inside the cavity followed by photolithography operations, and then etching the third layer.

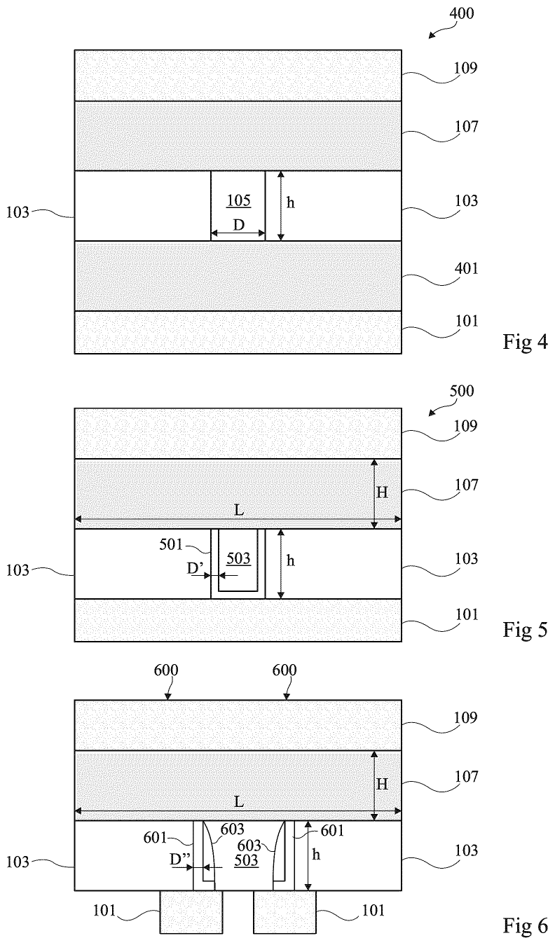

FIG. 4 is a partial schematic cross-sectional view of a phase-change memory cell 400 according to one embodiment.

The memory cell 400 shown in FIG. 4 has elements in common with the memory cell 100 shown in FIG. 1. These common elements will not be detailed again below. The memory cell 400 shown in FIG. 4 differs from the memory cell 100 shown in FIG. 1 in that the memory cell 400 further comprises another region 401 made of a phase-change material, different from that of region 105, interposed vertically between the conductive layer 101 and region 105. The phase-change material of region 401 is, for example, substantially identical to that of region 107.

In the example illustrated, the region 401 coats the conductive layer 101, the region 401 being more precisely located on, and in contact with, the upper face of the conductive layer 101. In this example, the insulating region 103 and the region 105 made of phase-change material are located on, and in contact with, the upper face of the region 401. The region 401 made of phase-change material has, for example, a height, or thickness, and a maximum lateral dimension substantially equal, respectively, to the height H and the maximum lateral dimension L of the region 107 made of phase-change material. When viewed from above, region 401 has any shape, for example identical to that of region 107.

The presence of the region 401 in the memory cell 400 advantageously allows better thermal insulation of the region 105 made of phase-change material than in the memory cell 100 to be achieved. As a result, the memory cell 400 uses less energy than the memory cell 100 to produce substantially the same heating in the region 105. The memory cell 400 is therefore more energy-efficient than the memory cell 100.

FIG. 5 is a partial schematic cross-sectional view of a phase-change memory cell 500 according to one embodiment.

The memory cell 500 shown in FIG. 5 has elements in common with the memory cell 100 shown in FIG. 1. These common elements will not be detailed again below. The memory cell 500 shown in FIG. 5 differs from the memory cell 100 shown in FIG. 1 in that the memory cell 500 comprises, in place of region 105, a region 501 made of phase-change material formed in the thickness of the insulating region 103.

In the example shown, the region 501 has, in side view and cross-section, a U-shape comprising vertical portions, extending vertically over the entire thickness h of the insulating region 103, and a horizontal portion, extending laterally over and in contact with part of the upper face of the conductive layer 101. The vertical portions of region 501 each have a width D′ and are separated laterally from each other by an insulating region 503. The insulating region 503 is, for example, made of the same material as the insulating region 103. In the example shown, insulating region 503 is located on, and in contact with, the inner side faces and bottom of the U formed by region 501. When viewed from above, region 503 is interposed laterally between two substantially parallel strips corresponding to the flanks of region 501. In other words, the interior of the U formed by region 501 is entirely filled with a dielectric material (the material of insulating region 503, in this example). By way of example, the vertical walls of the U formed by region 501 have, when viewed from above, a rectangular, elliptical, square, or circular shape.

By way of example, region 501 is formed in a step analogous to step d) of the method previously described in relation to FIG. 1, in which the first layer made of the first phase-change material coats the side walls, or flanks, and bottom of the cavity formed in step c) but does not fill, i.e., does not completely fill, the cavity. The insulating region 503 is then formed, for example, by depositing a further insulating layer on the upper face side of the structure, the further insulating layer and the first layer then being planarized, for example by CMP with stop on the upper face of the insulating region 103.

Memory cell 500 has similar or identical advantages to memory cell 100.

FIG. 6 is a partial schematic cross-sectional view of a structure comprising two phase-change memory cells 600 according to one embodiment.

The structure shown in FIG. 6 has elements in common with the memory cell 500 shown in FIG. 5. These common elements will not be detailed again below. The structure shown in FIG. 6 differs from the memory cell 500 shown in FIG. 5 in that the structure shown in FIG. 6 comprises two regions 601 made of phase-change material each formed through the thickness of the insulating region 103.

In the example shown, each region 601 has an L-shape comprising a vertical part, extending vertically through the entire thickness h of the insulating region 103, and a horizontal part, extending laterally over and in contact with part of the upper face of the conductive layer 101. In this example, the conductive layer 101 is discontinuous, and each memory cell 600 comprises a portion of conductive layer 101 isolated from portions of conductive layer 101 forming part of the other memory cells. The vertical part of the region 601 has a width D″. In the example shown, the Ls formed by the regions 601 of the memory cells 600 are symmetrical with respect to a vertical axis equidistant from the conductive layer portions 101, and are separated laterally from each other by the insulating region 503. By way of example, the vertical walls of the Ls formed by the regions 601 have a rectangular, elliptical, square, or circular shape, when viewed from above.

In the example shown, an insulating region 603 coats the upper face of the horizontal part and a flank of the vertical part of the L formed by each region 601. For example, the insulating region 603 is a spacer-type structure. By way of example, region 603 is made of a nitride, such as silicon nitride, gallium nitride (GaN) or silicon-carbon nitride (SiCN), or of silicon carbide (SiC).

By way of example, the regions 601 of the memory cells 600 shown in FIG. 6 are formed from the region 501 previously described in relation to FIG. 5, for example by photolithography, and then etching of the horizontal part of the U formed by the region 501. The insulating regions 603 are then formed, for example, by depositing and then etching an insulating layer before forming the insulating region 503, for example as described above in relation to FIG. 5. Thus, in the example shown in FIG. 6, two memory cells 600 are obtained from the same cavity.

Memory cells 600 have similar or identical advantages to those of memory cell 100.

Various embodiments and variants have been described. Those skilled in the art will understand that certain features of these embodiments can be combined and other variants will readily occur to those skilled in the art. In particular, the memory cell 400 shown in FIG. 4 may have a structure analogous to the structure 300 described in connection with FIG. 3, at the end of a step of initializing the memory cell 400 or during manufacture of the memory cell 400. In this case, the memory cell 400 comprises, for example, the region 301 made of phase-change material, interposed vertically between the regions 105 and 107, and another region made of phase-change material, analogous to the region 301, interposed vertically between the regions 105 and 401 and forming the symmetric of the region 301 with respect to a horizontal axis passing through the insulating region 103 at its center.

Furthermore, the embodiment shown in FIG. 4 can be combined with the embodiments shown in FIGS. 5 and 6. This means, for example, providing a region made of phase-change material in the memory cell 500 or 600 that is similar or identical to the region 401 of the memory cell 400, the region made of phase-change material then being interposed between the conductive layer 101 and the region 501, in the case of the memory cell 500, or the region 601, in the case of the memory cell 600.

Finally, the practical implementation of the embodiments and variants described herein is within the capabilities of those skilled in the art based on the functional description provided hereinabove. In particular, the chemical composition of each region 105, 107, 301, 401, 501, 601 made of phase-change material is adjustable by those skilled in the art, for example depending on the intended application, from the indications of the present description.

Furthermore, the embodiments described are not limited to the particular examples of materials and dimensions mentioned in the present description.

A phase-change memory cell (100; 300; 400; 500; 600) of the confined type is summarized as including: an insulating region (103); a first confined region (105; 501; 601) made of a first alloy (205) of germanium, antimony, and tellurium laterally surrounded by the insulating region, the first alloy forming entirely the first confined region; and a second region (107) made of a second alloy (207) of germanium, antimony, and tellurium, the second alloy including proportions different from the proportions of the first alloy, the second region overlapping the insulating region and the first region.

The first alloy (205) has: an atomic concentration of germanium of between 35 and 65%; and a ratio of atomic concentration of antimony to atomic concentration of tellurium of between 1 and 5.

The second alloy (207) has: an atomic concentration of germanium of between 40 and 80%; and a ratio of atomic concentration of antimony to atomic concentration of tellurium of between 0.2 and 1.

The first region (105; 501; 601) has a thickness (h) higher than 5 nm, preferably higher than 10 nm; and the second region (107) has a thickness (H) higher than 5 nm, preferably higher than 10 nm.

The cell (400) further includes a third region (401) made of the second alloy (207) located on the side of a face of the insulating region (103) opposite the second region (107), the insulating region (103), and the first region (105) being located on, and in contact with, the third region.

The second region (107) is located on, and in contact with, the insulating region (103) and the first region (105; 501; 601).

The cell (300) further includes a fourth region (301) made of a third alloy of germanium, antimony, and tellurium different from the first and second alloys (205, 207), interposed between the first and second regions (105, 107; 501, 107; 601, 107).

The cell (400) further includes fourth and fifth regions made of a third alloy of germanium, antimony, and tellurium different from the first and second alloys (205, 207), and: the fourth region is interposed between the first and second regions (105, 107); and the fifth region is interposed between the first and third regions (105, 401).

The first region (501) is U-shaped, the interior of the U formed by the first region being completely filled with a dielectric material.

The first region (601) is L-shaped.

A spacer made of silicon nitride (603) coats the upper face of the horizontal portion and a flank of the vertical portion of the L formed by each first region (601).

The first region has a maximum lateral dimension (D; D′; D″) strictly smaller than that (L) of the second region (107).

The first region (105; 501; 601) has a thickness (h) strictly less than that (H) of the second region (107).

A phase-change memory device is summarized as including a plurality of memory cells (100; 300; 400; 500; 600).

A method of manufacturing a phase-change memory cell (100; 300; 400; 500; 600) is summarized as including the following successive steps: a) forming an insulating region (103); b) forming an opening in the insulating region; c) filling the opening with a first region (105; 501; 601) made of a first alloy (205) of germanium, antimony, and tellurium laterally surrounded by the insulating region; and d) depositing, on the insulating region and the first region, a second region (107) of a second alloy (207) of germanium, antimony, and tellurium, the second alloy including proportions different from the proportions of the first alloy, the second region overlapping the insulating region and the first region.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A phase-change memory cell comprising:
an insulating region having a first surface opposite a second surface;
a first confined region made of a first alloy of germanium, antimony, and tellurium laterally surrounded by the insulating region, the first alloy entirely forming the first confined region, the first region extending entirely from the first surface to the second surface; and
a second region made of a second alloy of germanium, antimony, and tellurium, the second alloy comprising first proportions of germanium, antimony, and tellurium different from second proportions of germanium, antimony, and tellurium of the first alloy, the second region overlapping the first surface of the insulating region and the first region.

2. The cell according to claim 1, wherein the first alloy has an atomic concentration of germanium of between 35 and 65% and a ratio of atomic concentration of antimony to atomic concentration of tellurium of between 1 and 5.

3. The cell according to claim 1, wherein the second alloy has an atomic concentration of germanium of between 40 and 80% and a ratio of atomic concentration of antimony to atomic concentration of tellurium of between 0.2 and 1.

4. The cell according to claim 1, wherein:
the first region has a first thickness greater than 5 nm; and
the second region has a second thickness greater than 5 nm.

5. The cell according to claim 1, further comprising a third region made of the second alloy on a face of the insulating region opposite the second region, the insulating region and the first region being located on, and in contact with, the third region.

6. The cell according to claim 1, wherein the second region is on, and in contact with, the insulating region and the first region.

7. The cell according to claim 1, further comprising a fourth region made of a third alloy of germanium, antimony, and tellurium different from the first and second alloys, interposed between the first and second regions.

8. The cell according to claim 4, further comprising fourth and fifth regions made of a third alloy of germanium, antimony, and tellurium different from the first and second alloys, and wherein:
the fourth region is interposed between the first and second regions; and
the fifth region is interposed between the first and third regions.

9. The cell according to claim 1, wherein the first region is U-shaped, the interior of the U formed by the first region being completely filled with a dielectric material.

10. The cell according to claim 1, wherein the first region is L-shaped.

11. The cell according to claim 10, wherein a spacer made of silicon nitride coats the upper face of a horizontal portion and a flank of a vertical portion of the L-shaped first region.

12. The cell according to claim 1, wherein the first region has a first maximum dimension along a first direction extending from a first sidewall of the insulating region to a second sidewall of the insulating region smaller than a second maximum dimension of the second region along the first direction.

13. The cell according to claim 1, wherein the first region has a first thickness along a second direction transverse to the first direction smaller than a second thickness of the second region along the second direction.

14. The cell according to claim 1, wherein:
the first region has a first thickness greater than 10 nm; and
the second region has a second thickness greater than 10 nm.

15. A method of manufacturing a phase-change memory cell comprising:
forming an insulating region on a conductive layer;
forming an opening in the insulating region;
filling the opening with a first region made of a first alloy of germanium, antimony, and tellurium laterally surrounded by the insulating region; and
depositing, on the insulating region and the first region, a second region of a second alloy of germanium, antimony, and tellurium, the second alloy comprising first proportions of germanium, antimony, and tellurium different from second proportions of germanium, antimony, and tellurium of the first alloy, the second region overlapping the insulating region and the first region, the first region extending entirely through the insulating region along a first direction from the conductive layer to the second region.

16. The method according to claim 15, wherein the filling the opening with the first region includes:
depositing the first alloy into the opening and onto a surface of the insulating region; and
removing a portion of the first alloy on the surface of the insulating region.

17. The method according to claim 15, further comprising forming a second conductive layer on the second region.

18. A device, comprising:
a conductive layer an insulating region on the conductive layer, the insulating region having a first surface opposite the conductive layer along a first direction;
a first region in the insulating region extending along the first direction entirely through the insulating region from the first surface to the conductive layer, the first region including a first phase-change material;
a first dielectric portion extending into the first region from the first surface along the first direction, a first portion of the first region being between the first dielectric portion and the conductive layer; and
a second region on the insulating region and the first region, the second region including a second phase-change material different than the first phase-change material.

19. The device according to claim 18, wherein the first phase-change material is a first alloy of germanium, antimony, and tellurium and the second phase-change material is a second alloy of germanium, antimony, and tellurium, the second phase-change material has a ratio of antimony to tellurium different than a ratio of antimony to tellurium of the first phase-change material.

20. The device according to claim 18, wherein the first region is u-shaped with a first and a second portion extending along the first direction, the first dielectric portion being between the first and second portions of the first region.
